(19) United States
(12) Patent Application Publication
(10) Pub. No.: US 2024/0266479 A1
(43) Pub. Date: Aug. 8, 2024

(54) QUANTUM DOT SUBSTRATE, METHOD OF MANUFACTURING THEREOF, AND DISPLAY PANEL

(71) Applicant: Shenzhen China Star Optoelectronics Semiconductor Display Technology Co., Ltd., Shenzhen (CN)

(72) Inventors: Zhiqing SHI, Shenzhen (CN); Jinyang ZHAO, Shenzhen (CN); Lixuan CHEN, Shenzhen (CN)

(73) Assignee: Shenzhen China Star Optoelectronics Semiconductor Display Technology Co., Ltd., Shenzhen (CN)

(21) Appl. No.: 18/522,307

(22) Filed: Nov. 29, 2023

(30) Foreign Application Priority Data
Feb. 3, 2023 (CN) 202310122285.5

(51) Int. Cl. H01L 33/50; H01L 33/38

(52) U.S. Cl. CPC H01L 33/505; H01L 33/382; H01L 2933/0016; H01L 2933/0041

(57) ABSTRACT

A quantum dot substrate, a method of manufacturing thereof, and a display panel are provided by the present disclosure. The quantum dot substrate includes a substrate, a dam, a first electrode, a second electrode, and a quantum dot layer. The dam is located on the substrate and enclosed to form grooves. The first electrode is located on the substrate and in the grooves. The second electrode located on the dam. The quantum dot layer is located on the first electrode and in the grooves.

### CROSS-REFERENCE TO RELATED DISCLOSURE

This application claims the benefit of priority of Chinese Patent Application No. 202310122285.5, filed on Feb. 3, 2023, the contents of which are all incorporated by reference as if fully set forth herein in their entirety.

### TECHNICAL FIELD

The present disclosure relates to display technologies, and in particular, to a quantum dot substrate, a method of manufacturing thereof, and a display panel.

### BACKGROUND

Quantum dot (QD) is a kind of nanoscale semiconductor material with a quantum fluorescence effect, which may emit fluorescence with different colors under the excitation of electricity or light. The quantum dots have a series of unique optical properties, such as an adjustable spectrum with sizes, a narrow half-wave width of emission peak, a large stoke shift, and a high excitation efficiency. When the quantum dot is applied to a color filter of display panels, the display devices may be given a wider color gamut.

At present, a manufacturing method of the quantum dot color filter generally adopts inkjet printing, which needs fixed-point printing, so it is difficult to manufacture the color filter for high-resolution display panels due to limited printing accuracy.

Therefore, a quantum dot substrate, a method of manufacturing thereof, and a display panel are urgently needed to solve the technical problems above.

### SUMMARY

In view of the above, the embodiments of the present disclosure provide a quantum dot substrate, a method of manufacturing thereof, and a display panel to solve a technical problem that a quantum dot color filter manufactured by inkjet printing is difficult to be applied to high-resolution display panels.

The embodiment of the present disclosure provides a quantum dot substrate including a substrate, a dam located on the substrate and enclosed to form grooves, a first electrode located on the substrate and in the grooves, a second electrode located on the dam, and a quantum dot layer located on the first electrode and in the grooves.

In some embodiments, the grooves include first-type grooves, the first-type grooves include first sub-grooves, and the quantum dot layer includes a first quantum dot sub-layer located on the first electrode in the first sub-grooves.

In some embodiments, the first-type grooves further include second sub-grooves adjacent to the first sub-grooves in a first direction, and the quantum dot layer includes a second quantum dot sub-layer located on the first electrode in the second sub-grooves. A light-emitting color of the first quantum dot sub-layer is different from a light-emitting color of the second quantum dot sub-layer, and the first direction is parallel to an extension direction of one side edge of the quantum dot substrate.

In some embodiments, the grooves further include second-type grooves alternately arranged with the first-type grooves in the first direction.

In some embodiments, the quantum dot substrate further includes a barrier layer located on the second electrode, and the quantum dot includes barrier parts located on the second electrode between the first-type grooves and the second-type grooves.

In some embodiments, a thickness of the dam ranges from 1 μm to 15 μm, a thickness of the first electrode ranges from 500 nm to 2000 nm, and a thickness of the second electrode ranges from 500 nm to 2000 nm.

The embodiment of the present disclosure provides a method of manufacturing the quantum dot substrate, includes: forming a dam on a substrate enclosed to form grooves; forming a first electrode on the substrate and in the grooves; forming a second electrode on the dam; and forming a quantum dot layer on the first electrode and in the grooves.

In some embodiments, the forming the quantum dot layer on the first electrode and in the grooves includes: providing a first quantum dot solution including first quantum dots in first sub-grooves of the grooves; and applying a voltage to the first electrode and the second electrode, so that the first quantum dots are deposited on the first electrode located in the first sub-grooves to form a first quantum dot sub-layer on the first electrode located in the first sub-grooves.

In some embodiments, an electrical property of the first quantum dots is opposite to an electrical property of the first electrode in the first sub-grooves.

In some embodiments, the method further includes: providing a second quantum dot solution including second quantum dots in second sub-grooves of the grooves; and applying a voltage to the first electrode and the second electrode, so that the second quantum dots are deposited on the first electrode located in the second sub-grooves to form a second quantum dot sub-layer on the first electrode located in the second sub-grooves, and a light-emitting color of the first quantum dot sub-layer being different from a light-emitting color of the second quantum dot sub-layer.

In some embodiments, an electrical property of the second quantum dots is opposite to an electrical property of the first electrode in the second sub-grooves.

In some embodiments, the second sub-grooves are adjacent to the first sub-grooves in a first direction, and the first direction is parallel to an extension direction of one side edge of the quantum dot substrate.

In some embodiments, a first electric field is formed between the first electrode located in the first sub-grooves, and an intensity of the first electric field ranges from 5×10⁵ V/m to 5×10⁸ V/m.

In some embodiments, a thickness of the dam ranges from 1 μm to 15 μm, a thickness of the first electrode ranges from 500 nm to 2000 nm, and a thickness of the second electrode ranges from 500 nm to 2000 nm.

The embodiments of the present disclosure provide a display panel including a quantum dot substrate, the quantum dot substrate includes a substrate, a dam located on the substrate and enclosed to form grooves, a first electrode located on the substrate and in the grooves, a second electrode located on the dam, and a quantum dot layer located on the first electrode and in the grooves.

In the embodiments of the present disclosure, the first electrode and the second electrode are disposed on the quantum dot substrate, the quantum dot layer is formed on the first electrode under the action of the electric field formed by the first electrode and the second electrode, which improves the forming precision of the quantum dot layer, and it is conducive to manufacturing the quantum dot layer with high resolution in a large area and high efficiency.

### BRIEF DESCRIPTION OF THE DRAWINGS

To describe the technical solutions of the embodiments of the present disclosure more clearly, the following briefly introduces the accompanying drawings used in the description of the embodiments of the present disclosure. Apparently, the accompanying drawings described below illustrate only some exemplary embodiments of the present disclosure, and persons skilled in the art may derive other drawings from the drawings without making creative efforts.

FIG. 1 is a schematic structural diagram of a first structure of a quantum dot substrate according to an embodiment of the present disclosure.

FIG. 2 is a schematic structural diagram of a second structure of the quantum dot substrate according to an embodiment of the present disclosure.

FIG. 3 is a schematic structural diagram of a third structure of the quantum dot substrate according to an embodiment of the present disclosure.

FIG. 4 is a flowchart of a method of manufacturing the quantum dot substrate according to an embodiment of the present disclosure.

FIG. 5a to FIG. 5d are flow diagrams of the method of manufacturing the quantum dot substrate according to an embodiment of the present disclosure.

FIG. 6 is a structural diagram of applying a voltage to a first electrode and a second electrode according to an embodiment of the present disclosure.

### DETAILED DESCRIPTION

The technical solutions in embodiments of the present disclosure will be described clearly and completely hereafter with reference to the accompanying drawings. Apparently, described embodiments are only a part of but not all embodiments of the present disclosure. All other embodiments obtained by persons of ordinary skill in the art based on the embodiments of the present disclosure without creative efforts shall fall within a protection scope of the present disclosure. In addition, it should be understood that specific embodiments described herein are merely for explaining the present disclosure, the term “embodiment” used in a context means an example, instance, or illustration, and the present disclosure is not limited thereto. In the present disclosure, location terms such as “up” and “down” are used in general to refer to up and down in actual use or operation of a device, in particular drawing directions in the drawings, without description to the contrary. While “inside” and “outside” are for the outline of the device.

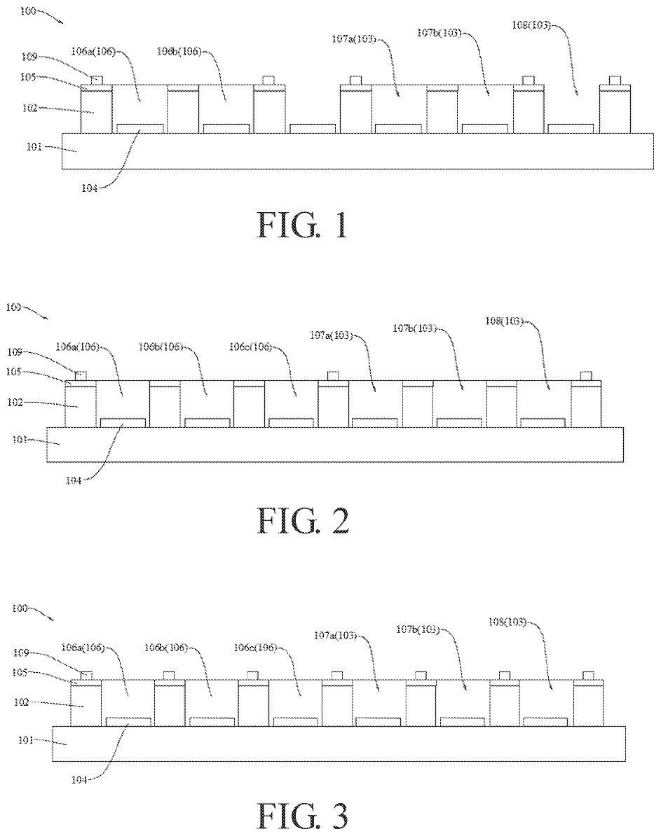

Referring to FIGS. 1 to 3, an embodiment of the present disclosure provides a quantum dot substrate 100 including a substrate 101, a dam 102 located on the substrate 101 and enclosed to form grooves 103, a first electrode 104 located on the substrate 101 and in the grooves 103, a second electrode 105 located on the dam 102, and a quantum dot layer 106 located on the first electrode 104 and in the grooves 103.

In the embodiment of the present disclosure, by forming the first electrode 104 and the second electrode 105 on the quantum dot substrate 100, the quantum dot layer 106 is formed on the first electrode 104 under the action of an electric field formed by the first electrode 104 and the second electrode 105, which improves the forming precision of the quantum dot layer 100, and it is conducive to manufacturing the quantum dot layer 106 with high resolution in a large area and high efficiency.

The technical solution of the present disclosure is described in conjunction with specific embodiments.

Referring to FIGS. 1 to 3, in the embodiment of the present disclosure, the grooves 103 include first-type grooves including first sub-grooves 107a. The quantum dot layer 106 includes a first quantum dot sub-layer 106a located on the first electrode 104 in the first sub-grooves 107a.

In some embodiments, the first-type grooves further include second sub-grooves 107b, and the quantum dot layer 106 includes a second quantum dot sub-layer 106b.

The second sub-grooves 107b are adjacent to the first sub-grooves 107a in a first direction. The second quantum dot sub-layer 106b is located on the first electrode 104 in the second sub-grooves 107b. A light-emitting color of the first quantum dot sub-layer 106a is different from a light-emitting color of the second quantum dot sub-layer 106b.

The quantum dot substrate 100 includes two first side edges disposed oppositely and two second side edges connected to the first side edges. The first direction may be parallel to an extension direction of the first side edges.

The first quantum dot sub-layer 106a includes first quantum dots, which may be red quantum dots or green quantum dots. When the first quantum dots are red quantum dots, the first quantum dots emit red light under the excitation of electricity or light. When the first quantum dots are green quantum dots, the first quantum dots emit green light under the excitation of electricity or light. The second quantum dot sub-layer 106b includes second quantum dots, which may be red quantum dots or green quantum dots, and a color of the second quantum dots is different from a color of the first quantum dots.

The first quantum dots and/or the second quantum dots are composed of groups IV, II-VI, IV-VI, or III-V elements. In some embodiments, the first quantum dots and/or the second quantum dots are mainly composed of groups IVA, IIB-VIA, IIIA-VA, and IVA-VIA elements. For example, when the first quantum dots and/or the second quantum dots are composed of the group IVA elements, the first quantum dots and/or the second quantum dots may include carbon quantum dots, silicon quantum dots, or germanium quantum dots. When the first quantum dots and/or the second quantum dots are composed of the groups IIB-VIA elements, the first quantum dots and/or the second quantum dots may specifically include zinc sulfide quantum dots or cadmium sulfide quantum dots. When the first quantum dots and/or the second quantum dots are composed of the groups IIIA-VA elements, the first quantum dots and/or the second quantum dots may specifically include indium phosphide quantum dots, gallium arsenide quantum dots, or indium arsenide quantum dots. When the first quantum dots and/or the second quantum dots are composed of the groups IVA-VIA elements, the first quantum dots and/or the second quantum dots may specifically include lead sulfide quantum dots, lead selenide quantum dots, or lead telluride quantum dots. Certainly, the first quantum dots and/or the second quantum dots may further include high-stability composite quantum dots, such as hydrogel-loaded quantum dots, cadmium selenide-silicon dioxide quantum dots, or perovskite quantum dots. It may be understood that specific materials of the first quantum dots and/or the second quantum dots may be appropriately modified and selected according to actual conditions and specific requirements.

In some embodiments, the grooves 103 include second-type grooves 108 alternately with the first-type grooves in the first direction.

Referring to FIG. 1, when the quantum dot substrate 100 is used as a color filter substrate, the quantum dot layer 106 may not be provided in the second-type grooves 108, and blue light from a backlight module directly passes through the second-type grooves 108 without color conversion of the quantum dot layer 106.

The quantum dot substrate 100 further includes a third color layer whose color is different from the colors of the first quantum dot sub-layer 106a and the second quantum dot sub-layer 106b, and the third color layer may be blue. The third color layer may be a third quantum dot sub-layer 106c including a third quantum dot, whose material selection range is the same as a material selection range of the first quantum dots and/or the second quantum dots, which will not be described herein.

In some embodiments, a thickness of the quantum dot layer 106 ranges from 1 μm to 15 μm. In one embodiment, the thickness of the quantum dot layer 106 ranges from 2 μm to 10 μm, such as 3 μm, 4 μm, 5 μm, 6 μm, 7 μm, 8 μm, and 9 km.

In some embodiments, a resolution of the quantum dot layer 106 is greater than or equal to 100 pixel-per-inch (ppi), and a resolution of the quantum dot layer 106 is less than or equal to 1500 ppi, such as 500 ppi and 1000 ppi, which is suitable for high-resolution display panels.

Referring to FIGS. 1 to 3, in some embodiments, the quantum dot substrate 100 further includes a barrier layer located on the second electrode 105.

The barrier layer includes barrier parts 109 located at least on the second electrode 105 between the second-type grooves 108 and the first-type grooves.

In some embodiments, the barrier parts 109 are located on the second electrode 105 between the first sub-grooves 107a and the second-type grooves 108; and/or, the barrier parts 109 are located on the second electrode 105 between the second sub-grooves 107b and the second-type grooves 108. An orthographic projection of each of the barrier parts 109 on the substrate 101 is within an orthographic projection of the second electrode 105 between the second-type grooves 108 and the first-type grooves on the substrate 101.

In some embodiments, the barrier layer further includes first openings disposed corresponding to the first-type grooves and exposing the second electrode 105. The first openings are disposed corresponding to the first-type grooves, i.e. the first opening is communicated with the first-type grooves.

The barrier layer further includes second openings disposed corresponding to the second-type grooves 108 and exposing the second electrode 105. The second openings are disposed corresponding to the second-type grooves 108, i.e. the second opening is communicated with the second-type grooves 108.

In some embodiments, the barrier parts 109 are further located on the second electrode 105 between the first sub-grooves 107a and the second sub-grooves 107b.

In some embodiments, the barrier parts 109 extend in a second direction, which intersects with the first direction.

By disposing the barrier layer, when the first quantum dot sub-layer 106a and/or the second quantum dot sub-layer 106b is formed, a first quantum dot solution and/or a second quantum dot solution may cover the second electrode 105, thereby forming the first quantum dot sub-layer 106a and/or the second quantum dot sub-layer 106b, reducing the covering accuracy requirement of the quantum dot solution when the quantum dot layer 106 is formed, and improving the formation efficiency of the quantum dot layer 106.

In some embodiments, a thickness of the dam ranges from 1 μm to 15 μm, such as 2 μm, 3 μm, 4 μm, 5 μm, 6 μm, 7 μm, 8 μm, 9 μm, 10 μm, 11 μm, 12 μm, 13 μm, and 14 μm, so that a depth of the grooves 103 may accommodate the first quantum dot solution and/or the second quantum dot solution with a suitable volume to form the first quantum dot sub-layer 106a and/or the second quantum dot sub-layer 106b with a suitable thickness. A material of the dam 102 may be an organic light-curing material, an organic heat-curing material, or an inorganic material. The organic light-curing material may be selected from acrylate compounds, which may specifically include one or more of methyl acrylate compounds, ethyl acrylate compounds, and propyl acrylate compounds. The organic thermosetting material may be selected from the group consisting of epoxy resin-based compounds, which specifically include at least one of butene epoxy resin and a cyclopentadiene epoxy resin. The inorganic material may be selected from one or more of silicon oxide, silicon nitride, and silicon oxynitride.

In some embodiments, a material selection range of the barrier layer is the same as the material selection range of the dam 102, which will not be repeated herein. A thickness of the barrier layer ranges from 1 μm to 10 μm. For example, the thickness of the barrier layer may be 2 μm, 3 μm, 4 μm, 5 μm, 6 μm, 7 μm, 8 μm, 9 μm, etc.

In some embodiments, a thickness of the first electrode 104 ranges from 500 nm to 2000 nm, and a thickness of the second electrode 105 ranges from 500 nm to 2000 nm. For example, the thickness of the first electrode 104 may be 600 nm, 700 nm, 800 nm, 900 nm, 1000 nm, 1100 nm, 1200 nm, 1300 nm, 1400 nm, 1500 nm, 1600 nm, 1700 nm, 1800 nm, 1900 nm, etc. The thickness of the second electrode 105 may be 600 nm, 700 nm, 800 nm, 900 nm, 1000 nm, 1100 nm, 1200 nm, 1300 nm, 1400 nm, 1500 nm, 1600 nm, 1700 nm, 1800 nm, 1900 nm, etc. A material of the first electrode 104 and a material of the second electrode 105 may be one or more of indium tin oxide, indium gallium zinc oxide, indium gallium tin oxide, silver, copper, molybdenum, and aluminum. Certainly, the material of the conductive layers may be adaptively modified and selected according to actual situations and specific requirements, which is not uniquely limited herein.

In the quantum dot substrate 100 provided by the embodiment of the present disclosure, by forming the first electrode 104 and the second electrode 105 on the quantum dot substrate 100, the quantum dot layer 106 is formed on the first electrode 104 under the action of an electric field formed by the first electrode 104 and the second electrode 105, so that the precision of forming the quantum dot layer 100 is improved, and it is conducive to manufacturing the quantum dot layer 106 with high resolution in a large area and high efficiency.

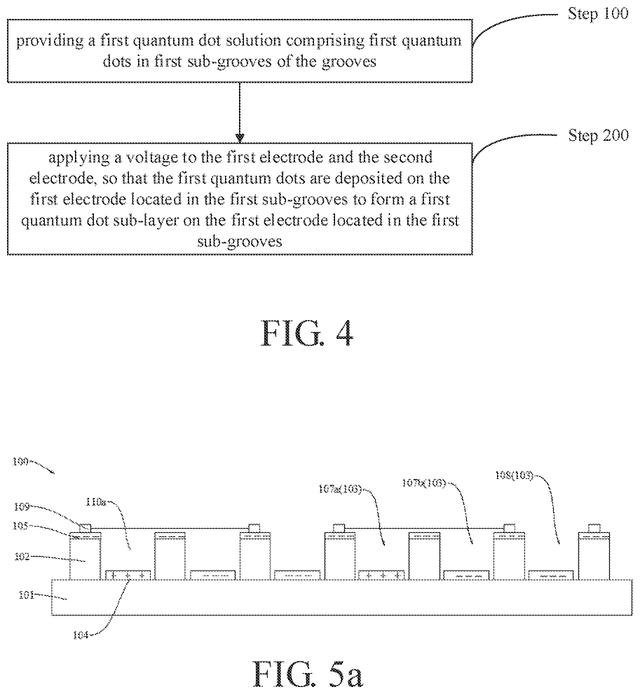

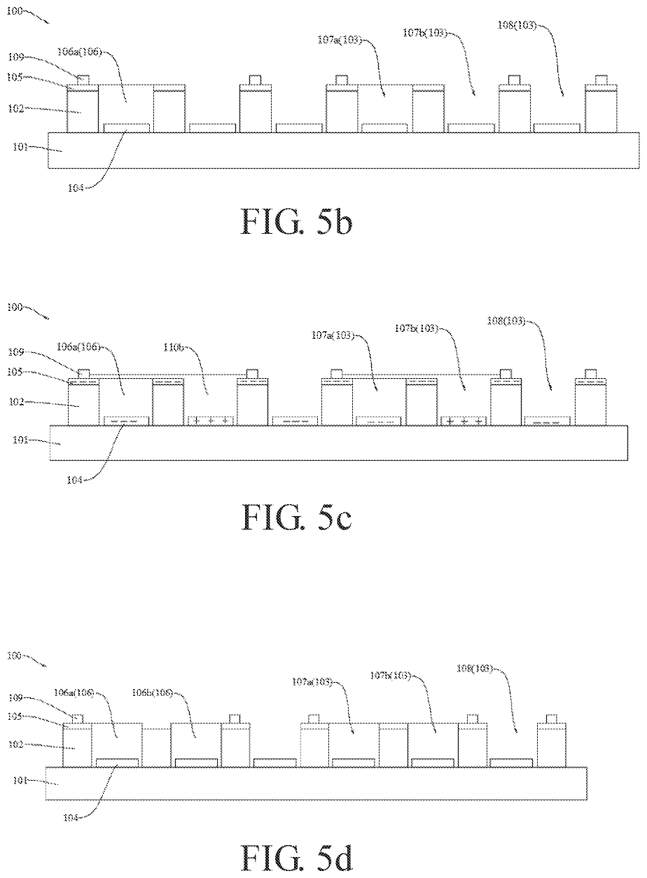

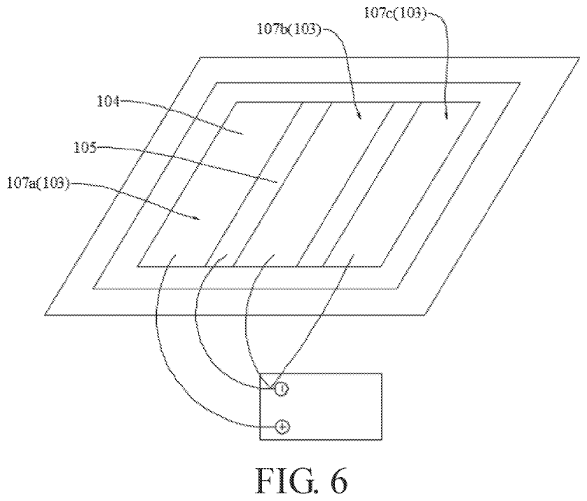

Referring to FIG. 4, FIGS. 5a-5d, and FIG. 6, the embodiment of the present disclosure further provides a manufacturing method of a quantum dot substrate, includes: providing a substrate; forming a dam on the substrate enclosed to form grooves; forming a first electrode on the substrate and in the grooves; forming a second electrode on the dam; and forming a quantum dot layer on the first electrode and in the grooves.

Referring to FIG. 5a, at step 100, providing a first quantum dot solution 110a including first quantum dots in first sub-grooves 107a of the grooves.

In some embodiments, the first quantum dot solution 110a is located in the second sub-grooves 107b and/or the second-type grooves 108 in addition to the first sub-grooves 107a.

In the first quantum dot solution 110a, a concentration of the first quantum dots is greater than or equal to 0.1 mg/ml, and less than or equal to 500 mg/ml, such as 0.5 mg/ml, 1 mg/ml, 50 mg/ml, 100 mg/ml, 150 mg/ml, 200 mg/ml, 250 mg/ml, 300 mg/ml, 350 mg/ml, 400 mg/ml, 450 mg/ml. When the first quantum dots are in the concentration range above, the first quantum dots may be well dispersed in a solvent without agglomeration and stably dispersed in the solvent, so that the electrophoretic deposition of the first quantum dots may be effectively promoted, and an electrophoretic deposition speed of the first quantum dots may be controlled to manufacture the first quantum dot sub-layer 106a with good morphology. The first quantum dot solution 110a further includes a first solvent, which may be selected from water, alcohols, ethers, esters, and alkanes. The first solvent may be ethanol, ether, ethyl acetate, and n-octane. Certainly, the first solvent may be appropriately modified according to the actual situations and specific requirements. For example, the first solvent may also be propylene glycol methyl ether acetate (PGMEA) or other compounds, which is not uniquely limited herein.

Referring to FIG. 5b and FIG. 6, at step 200, applying a voltage to the first electrode 104 and the second electrode 105, so that the first quantum dots are deposited on the first electrode 104 located in the first sub-grooves 107a to form a first quantum dot sub-layer 106a on the first electrode 104 located in the first sub-grooves 107a.

In some embodiments, a first electric field is formed between the first electrode 104 located in the first sub-grooves 107a and the second electrode 105, and an intensity of the first electric field ranges from 5×10⁵ V/m to 5×10⁸ V/m, such as, 1×10⁶ V/m, 5×10⁶ V/m, 1×10⁷ V/m, 2×10⁷ V/m, 3×10⁷ V/m, 4×10⁷ V/m, 5×10⁷ V/m, 2×10⁸ V/m, 3×10⁸ V/m, and 4×10⁸ V/m. When the intensity of the first electric field is within the range above, it is conducive to controlling the electrophoretic deposition rate of the first quantum dots to manufacture the first quantum dot sub-layer 106a with good morphology.

In some embodiments, the step 200 includes:
at step 210, applying the voltage to the first electrode 104 and the second electrode 105, so that the first electrode 104 in the first sub-grooves 107a has a first electrical property, the second electrode 105 has a second electrical property, the first electrode 104 in the second sub-grooves 107b has the second electrical property, and the first electrode 104 in the second-type grooves 108 has the second electrical property; a first electric field is formed between the first electrode 104 in the first sub-grooves 107a and the second electrode 105, a second electric field is formed between the first electrode 104 in the first sub-grooves 107a and the first electrode 104 in the second sub-grooves 107b, and a third electric field is formed between the first electrode 104 in the first sub-grooves 107a and the first electrode 104 in the second-type grooves 108. the first electric field, the second electric field, and the third electric field respectively act on the first quantum dots from a direction perpendicular to the substrate 101 and a direction horizontal to the substrate 101, which is further conducive to depositing the first quantum dots on the first electrode 104 in the first sub-grooves 107a, thereby forming the first quantum dot sub-layer 106a on the first electrode 104 in the first sub-grooves 107a.

The first electrical property is opposite to the second electrical property, and the first electrical property of the first electrode 104 in the first sub-grooves 107a is opposite to an electrical property of the first quantum dots. For example, when the first electrical property is positive, the electrical property of the first quantum dots is negative. When the first electrical property is negative, the electrical property of the first quantum dots is positive. The first electrical property of the first electrode 104 in the first sub-grooves 107a is opposite to the electrical property of the first quantum dots, so that the first quantum dots move towards the first electrode 104 in the first sub-grooves 107a under the action of the first electric field and is deposited on the first electrode 104 in the first sub-grooves 107a. The second electrical property is the same as the electrical property of the first quantum dots to prevent the first quantum dots from being deposited in the second sub-grooves 107b or the second-type grooves 108, thereby ensuring that the first quantum dot sub-layer 106a is finally formed in the first sub-grooves 107a.

The numerical ranges of the intensities of the first electric field, the second electric field, and the third electric field are same, which will not be described herein.

In some embodiments, time for applying the voltage to the first electrode 104 and the second electrode 105, i.e. the time for electrodeposition, is from 1 s to 3600 s, such as 60 s, 180 s, 300 s, 600 s, 1200 s, 1800 s, 2400 s, and 30000 s.

In some embodiments, the step 200 further includes step 220.

At step 220, clean the quantum dot substrate by using a first cleaning solvent.

The first electric field, the second electric field, and the third electric field may still be maintained during the cleaning process. The quantum dot substrate is cleaned with the first cleaning solvent to remove the first quantum dot solution 110a in the second sub-grooves 107b and the second-type grooves 108. At the same time, undeposited and residual quantum dots may be removed by cleaning the quantum dot substrate, it avoids that the layer structure manufactured on the quantum dot substrate may not be well attached due to the undeposited and residual quantum dots, which leads to a spalling problem.

The first cleaning solvent may be one or more of PGMEA, n-octane, cyclohexane, n-hexane, and n-dodecane.

In some embodiments, the step 200 further includes step 230.

At step 230, the first quantum dot sub-layer 106a is dried and cured for a first time under a first atmosphere and a first temperature.

The first temperature is from 25° C. to 160° C., the first atmosphere may be air, nitrogen, or helium, and the first time may be from 5 minutes to 12 hours.

The first electric field, the second electric field, and the third electric field may be maintained or removed during the drying and curing of the first quantum dot sub-layer 106a. By drying and curing the first quantum dot sub-layer 106a, the residual first solvent in the first quantum dot sub-layer 106a is further removed, a content of the first quantum dots in the first quantum dot sub-layer 106a is further increased, and a highest light-emitting brightness is achieved at a lower thickness.

In some embodiments, the manufacturing method of the quantum dot substrate further includes following steps:

Referring to FIG. 5c, at step 300, providing a second quantum dot solution 110b including second quantum dots in second sub-grooves 107b of the grooves.

In some embodiments, the second quantum dot solution 110b is located in the first sub-grooves 107a and/or the second-type grooves 108 in addition to the second sub-grooves 107b.

In the second quantum dot solution 110b, a concentration of the second quantum dots is greater than or equal to 0.1 mg/ml, and less than or equal to 500 mg/ml. When the second quantum dots are in the concentration range above, the second quantum dots may be well dispersed in the solvent without agglomeration, and stably dispersed in the solvent, so that the electrophoretic deposition of the second quantum dots may be effectively promoted, and an electrophoretic deposition speed of the second quantum dots may be controlled to manufacture the second quantum dot sub-layer 106b with good morphology. The second quantum dot solution 110b further includes a second solvent whose selection range is the same as the selection range of the first solvent, which will not be described herein.

Referring to FIG. 5d, at step 400, applying a voltage to the first electrode 104 and the second electrode 105, so that the second quantum dots are deposited on the first electrode 104 located in the second sub-groove 107b to form a second quantum dot sub-layer 106b on the first electrode 104 located in the second sub-grooves 107b.

In some embodiments, an intensity of the second electric field is greater than or equal to 5×10⁵ V/m, and less than or equal to 4×10⁷ V/m, such as, 1×10⁶ V/m, 5×10⁶ V/m, 1×10⁷ V/m, 2×10⁷ V/m, 3×10⁷ V/m, and 3.5×10⁷ V/m. When the intensity of the second electric field is within the range above, it is conducive to controlling the electrophoretic deposition rate of the second quantum dots to manufacture the second quantum dot sub-layer 106b with good morphology.

In some embodiments, the step 400 includes step 410.

At step 410, the voltage to the first electrode 104 and the second electrode 105 is applied, so that the first electrode 104 in the second sub-grooves 107b has a third electrical property, the second electrode 105 has a fourth electrical property, the first electrode 104 in the first sub-grooves 107a has the fourth electrical property, and the first electrode 104 in the second-type grooves 108 has the fourth electrical property. A fourth electric field is applied between the first electrode 104 in the second sub-grooves 107b and the second electrode 105, a fifth electric field is applied between the first electrode 104 in the first sub-grooves 107a and the first electrode 104 in the second sub-grooves 107b, and a sixth electric field is applied between the first electrode 104 in the second sub-groove 107b and the first electrode 104 in the second-type grooves 108. The fourth electric field, the fifth electric field, and the sixth electric field respectively act on the second quantum dots from the direction perpendicular to the substrate 101 and the direction horizontal to the substrate 101, which is further conducive to depositing the second quantum dots on the first electrode 104 in the second sub-grooves 107b, thereby forming the second quantum dot sub-layer 106b on the first electrode 104 in the second sub-grooves 107b.

The third electrical property is opposite to the fourth electrical property, and the third electrical property of the first electrode 104 in the second sub-grooves 107b is opposite to an electrical property of the second quantum dots. For example, when the third electrical property is positive, the electrical property of the second quantum dots is negative. When the third electrical property is negative, the electrical property of the second quantum dots is positive. The third electrical property of the first electrode 104 in the second sub-grooves 107b is opposite to the electrical property of the second quantum dots, so that the second quantum dots move towards the first electrode 104 in the second sub-grooves 107b under the action of the fourth electric field and is deposited on the first electrode 104 in the second sub-grooves 107b. The third electrical property is the same as the electrical property of the second quantum dots to prevent the second quantum dots from being deposited in the first sub-grooves 107a or the second-type grooves 108, thereby ensuring that the second quantum dot sub-layer 106a is finally formed in the second sub-grooves 107a. The electrical property of the second quantum dots and the electrical property of the first quantum dots are same or opposite. When the electrical property of the first quantum dots and the electrical property of the second quantum dots are same, a direction of the first electric field and a direction of the fourth electric field are same. When the electrical property of the first quantum dots and the electrical property of the second quantum dots are opposite, the direction of the first electric field and the direction of the fourth electric field are opposite.

The numerical ranges of the intensities of the fourth electric field, the fifth electric field, and the sixth electric field are same as a numerical range of the intensity of the first electric field, which will not be described herein.

In some embodiments, time for applying the voltage to the first electrode 104 and the second electrode 105 at the step 410 is the same as the time for applying the voltage to the first electrode 104 and the second electrode 105 at the step 210.

In some embodiments, the step 400 further includes step 420.

At step 420, clean the quantum dot substrate by using a second cleaning solvent.

The fourth electric field, the fifth electric field, and the sixth electric field may still be maintained during the cleaning process. The quantum dot substrate is cleaned with the second cleaning solvent to remove the second quantum dot solution 110b in the first sub-grooves 107a and the second-type grooves 108. At the same time, undeposited and residual quantum dots may be removed by cleaning the quantum dot substrate, it avoids that the layer structure manufactured on the quantum dot substrate may not be well attached due to the undeposited and residual quantum dots, which leads to the spalling problem.

The second cleaning solvent may be one or more of PGMEA, n-octane, cyclohexane, n-hexane, and n-dodecane.

In some embodiments, the step 400 further includes step 430.

At, the second quantum dot sub-layer 106b is dried and cured for a second time under a second atmosphere and a second temperature.

The second temperature is from 25° C. to 160° C., the second atmosphere may be air, nitrogen, or helium, and the second time may be from 5 minutes to 12 hours.

The fourth electric field, the fifth electric field, and the sixth electric field may be maintained or removed during drying and curing of the second quantum dot sub-layer 106b. By drying and curing the second quantum dot sub-layer 106b, the residual second cleaning solvent in the second quantum dot sub-layer 106b is further removed, a content of the second quantum dots in the second quantum dot sub-layer 106a is further increased, and the highest light-emitting brightness is achieved at a lower thickness.

In some embodiments, the manufacturing method of the quantum dot substrate further includes following steps:
at step 500, providing a third quantum dot solution including third quantum dots in the second-type grooves 108.

In some embodiments, the third quantum dot solution is located in the first sub-grooves 107a and/or the second sub-grooves 107b in addition to the second-type grooves 108.

In the third quantum dot solution, a concentration of the third quantum dots is greater than or equal to 0.1 mg/ml, and less than or equal to 500 mg/ml. When the third quantum dots are in the concentration range above, the third quantum dots may be well dispersed in a solvent without agglomeration, so that the third quantum dots may be stably dispersed in the solvent, the electrophoretic deposition of the third quantum dots may be effectively promoted, and an electrophoretic deposition speed of the third quantum dots may be controlled to manufacture the third quantum dot sub-layer 106c with good morphology. The third quantum dot solution further includes a third solvent whose selection range is the same as the selection range of the first solvent, which will not be described herein.

At step 600, a voltage is applied to the first electrode 104 and the second electrode 105, so that the third quantum dots are deposited on the first electrode 104 located in the second sub-groove 107b to form a third quantum dot sub-layer 106b on the first electrode 104 located in the second sub-grooves 107b.

An intensity range of the third electric field is the same as an intensity range of the first electric field, which will not be repeated herein.

In some embodiments, the step 600 includes:
at step 610, applying the voltage to the first electrode 104 and the second electrode 105, so that the first electrode 104 in the second sub-grooves 107b has a fifth electrical property, the second electrode 105 has a sixth electrical property, the first electrode 104 in the first sub-grooves 107a has the sixth electrical property, and the first electrode 104 in the second sub-groove 107b has the sixth electrical property; a seventh electric field is formed between the first electrode 104 in the second-type grooves 108 and the second electrode 105, a eighth electric field is formed between the first electrode 104 in the first sub-grooves 107a and the first electrode 104 in the second-type grooves 108, and a ninth electric field is formed between the first electrode 104 in the second sub-grooves 107b and the first electrode 104 in the second-type grooves 108; the seventh electric field, the eighth electric field, and the ninth electric field respectively act on the third quantum dots from the direction perpendicular to the substrate 101 and the direction horizontal to the substrate 101, which is further conducive to depositing the third quantum dots on the first electrode 104 in the second-type grooves 108, thereby forming the third quantum dot sub-layer 106c on the first electrode 104 in the second-type grooves 108.

The fifth electrical property is opposite to the sixth electrical property, and the fifth electrical property of the first electrode 104 in the second-type grooves 108 is opposite to an electrical property of the third quantum dots. For example, when the fifth electrical property is positive, the electrical property of the third quantum dots is negative. When the fifth electrical property is negative, the electrical property of the third quantum dots is positive. The fifth electrical property of the first electrode 104 in the second-type grooves 108 is opposite to the electrical property of the third quantum dots, so that the third quantum dots move towards the first electrode 104 in the second-type grooves 108 under the action of the seventh electric field and is deposited on the first electrode 104 in the second-type grooves 108. The fifth electrical property is the same as the electrical property of the third quantum dots to prevent the third quantum dots from being deposited in the first sub-grooves 107a or the second sub-grooves 107b, thereby ensuring that the third quantum dot sub-layer 106c is finally formed in the second-type grooves 108. The electrical property of the third quantum dots and the electrical property of the first quantum dots are same or opposite. When the electrical property of the first quantum dots and the electrical property of the third quantum dots are same, a direction of the first electric field and a direction of the seventh electric field are same. When the electrical property of the first quantum dots and the electrical property of the third quantum dots are opposite, the direction of the first electric field and the direction of the seventh electric field are opposite.

The numerical ranges of the intensities of the seventh electric field, the eighth electric field, and the ninth electric field are the same as the numerical range of the intensity of the first electric field, which will not be described herein.

In some embodiments, time for applying the voltage to the first electrode 104 and the second electrode 105 at the step 610 is the same as the time for applying the voltage to the first electrode 104 and the second electrode 105 at the step 210.

In some embodiments, the step 600 further includes step 620.

At step 620, clean the quantum dot substrate by using a third cleaning solvent.

The seventh electric field, the eighth electric field, and the ninth electric field may still be maintained during the cleaning process. The quantum dot substrate is cleaned with the third cleaning solvent to remove the third quantum dot solution in the first sub-grooves 107a and the second sub-grooves 107b. At the same time, undeposited and residual quantum dots may be removed by cleaning the quantum dot substrate, it avoids that the layer structure manufactured on the quantum dot substrate may not be well attached due to the undeposited and residual quantum dots, which leads to the spalling problem.

A selection range of the third cleaning solvent is the same as the selection ranges of a first cleaning solvent and the second cleaning solvent, which will not be described herein.

In some embodiments, the step 600 further includes step 630.

At step 630, the third quantum dot sub-layer 106c is dried and cured for a third time under a third atmosphere and a third temperature.

The third temperature is from 25° C. to 160° C., the third atmosphere may be air, nitrogen, or helium, and the third time may be from 5 minutes to 12 hours.

The seventh electric field, the eighth electric field, and the ninth electric field may be maintained or removed during drying and curing of the third quantum dot sub-layer 106c. By drying and curing the third quantum dot sub-layer 106c, the residual third cleaning solvent in the third quantum dot sub-layer 106c is further removed, a content of the third quantum dots in the third quantum dot sub-layer 106c is further increased, and the highest light-emitting brightness is achieved at a lower thickness.

In some embodiments, before the step 100, the manufacturing method of the quantum dot substrate further includes step 700 and step 800.

At step 700, the dam 102 is formed on the substrate 101, and the dam 102 is enclosed to form grooves.

In some embodiments, the step 700 includes: forming a dam material layer on an entire surface of the substrate 101, and patterning the dam material layer to obtain the dam 102. The material selection of the dam 102 has been described in the foregoing quantum dot substrate and will not be repeated herein. The dam material layer may be patterned by a photolithography process or an ion beam etching process. It may be understood that the dam material layer may be patterned in other ways depending on the actual situations and specific requirements, which is not uniquely limited herein.

At step 800, the first electrode 104 located in the grooves and the second electrode 105 located on the dam 102 are formed.

In some embodiments, the step 800 includes: forming a conductive layer on the substrate 101 and the dam 102; and patterning the conductive layer to obtain the first electrode 104 located in the grooves and the second electrode 105 located on the dam 102. The first electrode 104 and the second electrode 105 are formed by the same patterning process, which is beneficial to saving material cost, simplifying manufacturing process, and improving production efficiency. The material selections of the first electrode 104 and the second electrode 105 have been described in the quantum dot substrate mentioned above and will not be described herein. The conductive layer may be patterned by the photolithography process or the ion beam etching process. It may be understood that the conductive layer may be patterned in other ways according to the actual situations and specific needs, which is not uniquely limited herein.

At step 900, forming a barrier layer on the second electrode 105.

The barrier layer includes barrier parts 109 located at least on the second electrode 105 between the second-type grooves 108 and the first-type grooves.

In some embodiments, the step 900 includes: forming a barrier material layer on the entire surface of the substrate 101, the first electrode 104 and the second electrode 105, and patterning the barrier material layer to obtain the barrier layer. The material selection of the barrier layer has been introduced in the aforementioned quantum dot substrate, which will not be repeated herein. The barrier layer may be patterned by the photolithography process or the ion beam etching process. It may be understood that according to the actual situations and specific needs, other ways may be used to pattern the barrier material layer, which is not uniquely limited herein.

In the embodiment of the present disclosure, by forming the first electrode 104 and the second electrode 105 on the quantum dot substrate 100, the quantum dot layer 106 is formed on the first electrode 104 under the action of an electric field formed by the first electrode 104 and the second electrode 105, which improves the forming precision of the quantum dot layer 100, and it is conducive to manufacturing the quantum dot layer 106 with high resolution in a large area and high efficiency.

The embodiment of the present disclosure provides a display panel including the quantum dot substrate 100 in the embodiment mentioned above, or the quantum dot substrate 100 manufactured by the manufacturing method of the quantum dot substrate in the embodiment mentioned above.

The quantum dot substrate 100 may be used as a color filter substrate of the display panel, which may be one of a liquid crystal display panel, an organic light-emitting diode display panel, and a quantum dot light-emitting diode.

The embodiments of the present disclosure provide a quantum dot substrate, a method of manufacturing thereof, and a display panel. The quantum dot substrate includes the substrate, the dam on the substrate and enclosed to form the grooves, the first electrode in the grooves, the second electrode on the dam, and the quantum dot layer on the substrate and in the grooves. In the embodiment of the present disclosure, by forming the first electrode and the second electrode on the quantum dot substrate, the quantum dot layer is formed on the first electrode under the action of an electric field formed by the first electrode 104 and the second electrode, which improves the forming precision of the quantum dot layer 100, and it is conducive to manufacturing the quantum dot layer 106 with high resolution in a large area and high efficiency.

The present disclosure has been described in detail with respect to a quantum dot substrate, a method of manufacturing thereof, and a display panel according to an embodiment of the present disclosure. The principles and implementations of the present disclosure are described in detail here with specific examples. The above description of the embodiments is merely intended to help understand the method and core ideas of the present disclosure. At the same time, a person skilled in the art may make changes in the specific embodiments and disclosure scope according to the idea of the present disclosure. In conclusion, the content of the present specification should not be construed as a limitation to the present disclosure.

What is claimed is:

1. A quantum dot substrate, comprising:
a substrate;
a dam, located on the substrate and enclosed to form grooves;
a first electrode, located on the substrate and in the grooves;
a second electrode, located on the dam; and
a quantum dot layer, located on the first electrode and in the grooves.

2. The quantum dot substrate according to claim 1, wherein the grooves comprise first-type grooves, the first-type grooves comprise first sub-grooves, and the quantum dot layer comprises a first quantum dot sub-layer located on the first electrode in the first sub-grooves.

3. The quantum dot substrate according to claim 2, wherein the first-type grooves further comprise second sub-grooves adjacent to the first sub-grooves in a first direction, and the quantum dot layer comprises a second quantum dot sub-layer located on the first electrode in the second sub-grooves; a light-emitting color of the first quantum dot sub-layer is different from a light-emitting color of the second quantum dot sub-layer, and the first direction is parallel to an extension direction of one side edge of the quantum dot substrate.

4. The quantum dot substrate according to claim 3, wherein the grooves further comprise second-type grooves alternately arranged with the first-type grooves in the first direction.

5. The quantum dot substrate according to claim 4, further comprising:
a barrier layer, located on the second electrode and comprising barrier parts located on the second electrode between the first-type grooves and the second-type grooves.

6. The quantum dot substrate according to claim 1, wherein a thickness of the dam ranges from 1 μm to 15 μm, a thickness of the first electrode ranges from 500 nm to 2000 nm, and a thickness of the second electrode ranges from 500 nm to 2000 nm.

7. A method of manufacturing a quantum dot substrate, comprising:
forming a dam on a substrate enclosed to form grooves;
forming a first electrode on the substrate and in the grooves;
forming a second electrode on the dam; and
forming a quantum dot layer on the first electrode and in the grooves.

8. The method according to claim 7, wherein the forming the quantum dot layer on the first electrode and in the grooves comprises:
providing a first quantum dot solution comprising first quantum dots in first sub-grooves of the grooves; and
applying a voltage to the first electrode and the second electrode, so that the first quantum dots are deposited on the first electrode located in the first sub-grooves to form a first quantum dot sub-layer on the first electrode located in the first sub-grooves.

9. The method according to claim 8, wherein an electrical property of the first quantum dots is opposite to an electrical property of the first electrode in the first sub-grooves.

10. The method according to claim 9, further comprising:
providing a second quantum dot solution comprising second quantum dots in second sub-grooves of the grooves; and
applying a voltage to the first electrode and the second electrode, so that the second quantum dots are deposited on the first electrode located in the second sub-grooves to form a second quantum dot sub-layer on the first electrode located in the second sub-grooves, and a light-emitting color of the first quantum dot sub-layer is different from a light-emitting color of the second quantum dot sub-layer.

11. The method according to claim 10, wherein an electrical property of the second quantum dots is opposite to an electrical property of the first electrode in the second sub-grooves.

12. The method according to claim 11, wherein the second sub-grooves are adjacent to the first sub-grooves in a first direction, and the first direction is parallel to an extension direction of one side edge of the quantum dot substrate.

13. The method according to claim 8, wherein a first electric field is formed between the first electrode located in the first sub-grooves and the second electrode, and an intensity of the first electric field ranges from 5×10⁵ V/m to 5×10⁸ V/m.

14. The method according to claim 7, wherein a thickness of the dam ranges from 1 μm to 15 μm, a thickness of the first electrode ranges from 500 nm to 2000 nm, and a thickness of the second electrode ranges from 500 nm to 2000 nm.

15. A display panel comprising a quantum dot substrate, wherein the quantum dot substrate comprises:
a substrate;
a dam, located on the substrate and enclosed to form grooves;
a first electrode, located on the substrate and in the grooves;
a second electrode, located on the dam; and
a quantum dot layer, located on the first electrode and in the grooves.

16. The display panel according to claim 15, wherein the grooves comprise first-type grooves, the first-type grooves comprise first sub-grooves, and the quantum dot layer comprises a first quantum dot sub-layer located on the first electrode in the first sub-grooves.

17. The display panel according to claim 16, wherein the first-type grooves further comprise second sub-grooves adjacent to the first sub-grooves in a first direction, and the quantum dot layer comprises a second quantum dot sub-layer located on the first electrode in the second sub-grooves; a light-emitting color of the first quantum dot sub-layer is different from a light-emitting color of the second quantum dot sub-layer, and the first direction is parallel to an extension direction of one side edge of the quantum dot substrate.

18. The display panel according to claim 17, wherein the grooves further comprise second-type grooves alternately arranged with the first-type grooves in the first direction.

19. The display panel according to claim 18, wherein the quantum dot substrate further comprises:
a barrier layer, located on the second electrode and comprising barrier parts located on the second electrode between the first-type grooves and the second-type grooves.

20. The display panel according to claim 15, wherein a thickness of the dam ranges from 1 μm to 15 μm, a thickness of the first electrode ranges from 500 nm to 2000 nm, and a thickness of the second electrode ranges from 500 nm to 2000 nm.
